(19) United States
(12) Patent Application Publication
(10) Pub. No.: US 2026/0173956 A1
(43) Pub. Date: Jun. 18, 2026

(54) SEMICONDUCTOR PACKAGE HAVING HIGH-VOLTAGE STACKED TRANSISTORS AND METHOD OF MAKING THE SAME

(71) Applicant: ALPHA AND OMEGA SEMICONDUCTOR INTERNATIONAL LP, TORONTO (CA)

(72) Inventors: Zhiqiang Niu, Santa Clara, CA (US); Lin Chen, San Jose, CA (US); Long-Ching Wang, Cupertino, CA (US); Bo Chen, Shanghai (CN); Jia-long Yuan, Shanghai (CN); Yan Xun Xue, Los Gatos, CA (US); Xiao Zhang, Sunnyvale, CA (US); Lin Wang, Shanghai (CN)

(73) Assignee: ALPHA AND OMEGA SEMICONDUCTOR INTERNATIONAL LP, TORONTO (CA)

(21) Appl. No.: 18/984,792

(22) Filed: Dec. 17, 2024

(51) Int. Cl. H01L 25/07; H01L 21/56; H01L 23/00; H01L 23/31; H01L 23/495

(52) U.S. Cl. CPC H10W 90/00; H10W 70/481; H10W 74/016; H10W 74/114; H10W 90/811; H10W 72/0198; H10W 72/889; H10W 74/10; H10W 90/756; H10W 90/766; H10W 90/796

(57) ABSTRACT

A semiconductor package comprises a lead frame, a first high-voltage field-effect transistor (FET), a source clip, a gate clip, a second high-voltage FET, a drain clip or a bond wire, and a molding encapsulation. A method comprises the steps of providing a lead frame; mounting a first high-voltage FET; attaching a source clip and a gate clip; mounting a second high-voltage FET; attaching a drain clip or a bond wire, forming a molding encapsulation; and applying a singulation process.

### FIELD OF THE INVENTION

This invention relates generally to a semiconductor package and a method of making the same. More particularly, the present invention relates to the semiconductor package having high-voltage, stacked field-effect transistors (FETs) and the method of making the same.

### BACKGROUND OF THE INVENTION

Conventional metal-oxide-silicon field-effect transistor (MOSFET) including high-voltage, stacked FETs experiences electrical coupling issue.

A gate clip and a source clip of the semiconductor package of the present disclosure includes features to facilitate maintaining high voltage insulation distance.

### SUMMARY OF THE INVENTION

The present invention discloses a semiconductor package comprising a lead frame, a first high-voltage FET, a source clip, a gate clip, a second high-voltage FET, a drain clip or a bond wire, and a molding encapsulation.

A method for fabricating a semiconductor package is also disclosed. The method comprises the steps of providing a lead frame; mounting a first high-voltage FET; attaching a source clip and a gate clip; mounting a second high-voltage FET; attaching a drain clip or a bond wire, forming a molding encapsulation; and applying a singulation process.

### BRIEF DESCRIPTION OF THE DRAWINGS

FIG. 1A is a top perspective view, FIG. 1B is a bottom perspective view, FIG. 1C is a top perspective view without molding encapsulation, and FIG. 1D is a side view of a semiconductor package in examples of the present disclosure. FIG. 1E is a bottom perspective view of a gate clip and a source clip in examples of the present disclosure.

FIG. 2 is a side view of another semiconductor package in examples of the present disclosure.

FIG. 3 is a flowchart of a process to develop a semiconductor package in examples of the present disclosure.

FIG. 4AA, 4BA, 4CA, 4DA, 4EA, 4FA, and 4GA, show top perspective views and FIG. 4AB, 4BB, 4CB, 4DB, 4EB, 4FB, and 4GB, show side views of the process of FIG. 5 to fabricate the semiconductor package in examples of the present disclosure.

### DETAILED DESCRIPTION OF THE INVENTION

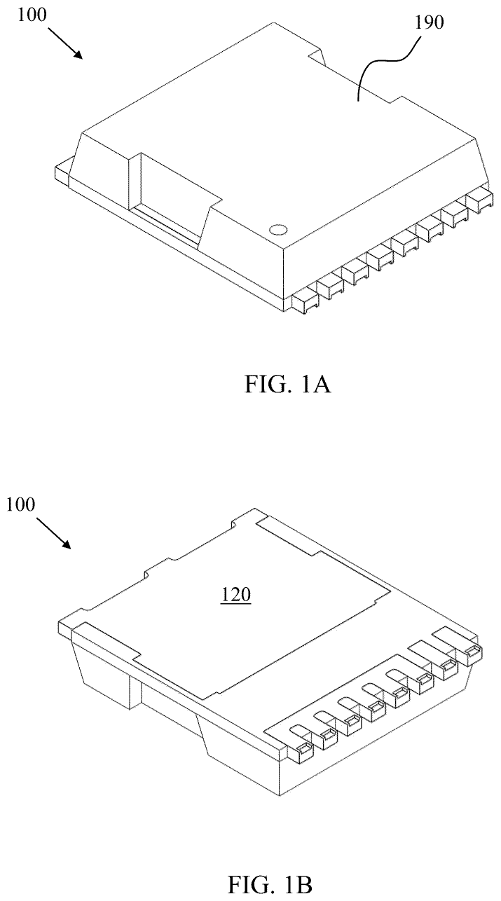

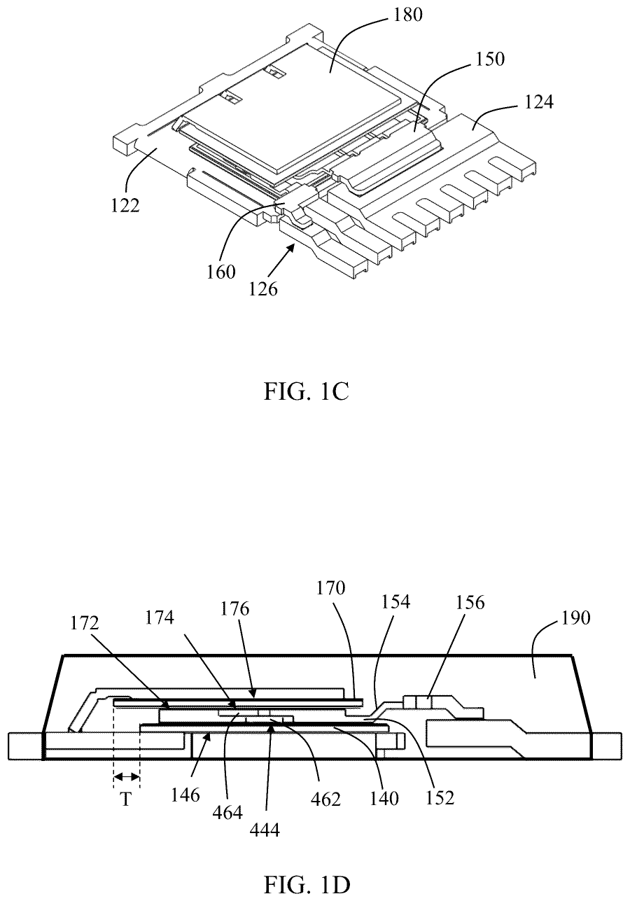

FIG. 1A is a top perspective view, FIG. 1B is a bottom perspective view, FIG. 1C is a top perspective view without molding encapsulation, and FIG. 1D is a side view of a semiconductor package 100 in examples of the present disclosure. In examples of the present disclosure, the semiconductor package 100 is a transistor outline leadless (TOLL) surface mounting device (SMD).

The semiconductor package 100 comprises a lead frame 120, a first high-voltage FET 140, a source clip 150, a gate clip 160, a second high-voltage FET 170, at least a majority portion of a drain clip 180, and a molding encapsulation 190.

In examples of the present disclosure, the semiconductor package 100 is of a first rectangular prism shape. The first high-voltage FET 140 is of a second rectangular prism shape. The second high-voltage FET 170 is of a third rectangular prism shape.

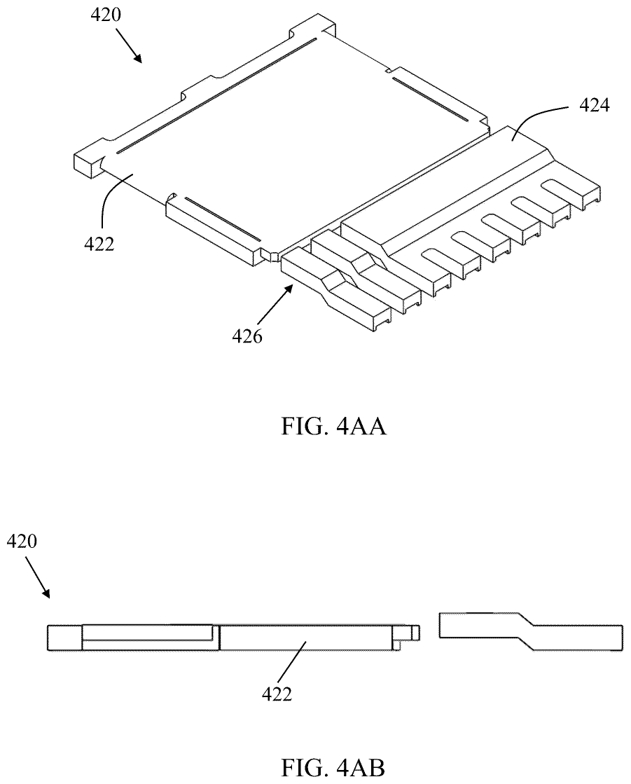

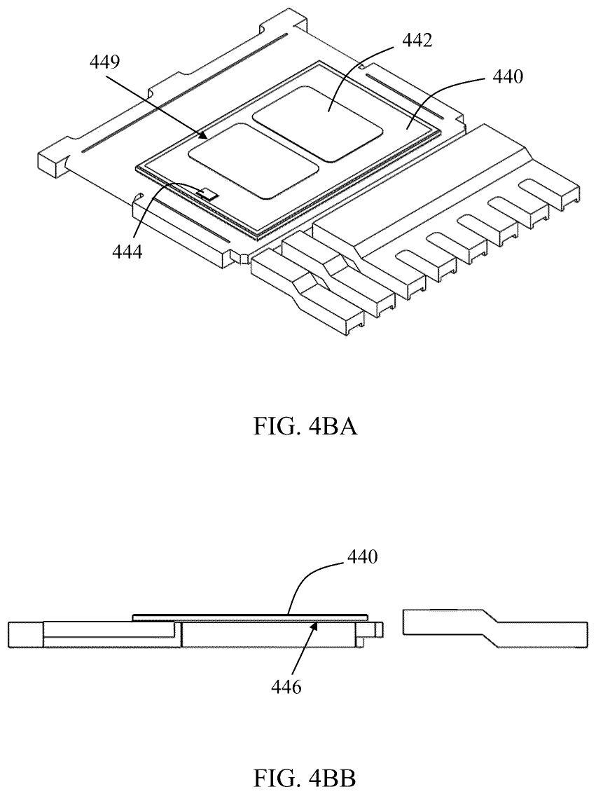

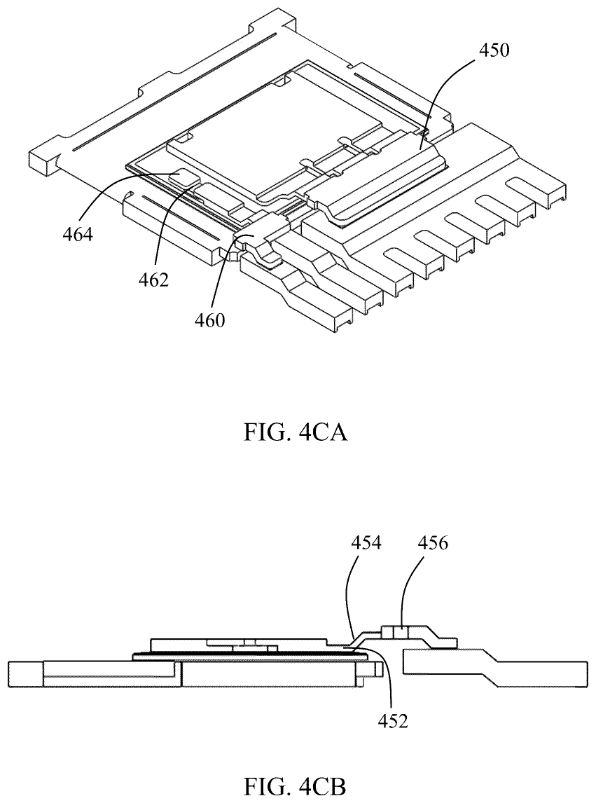

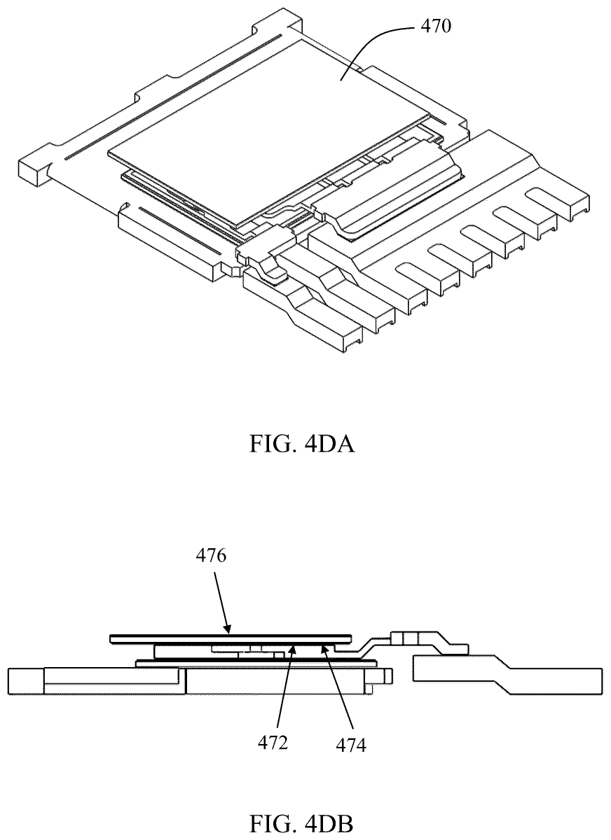

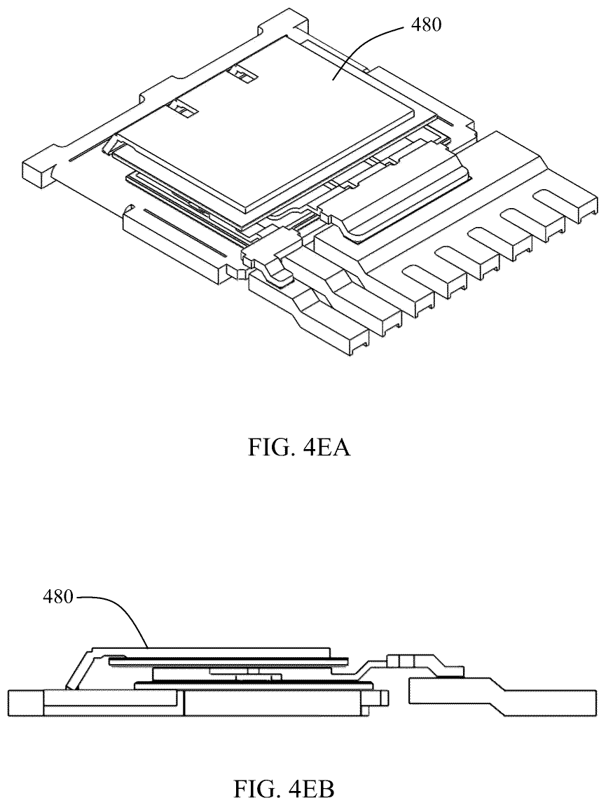

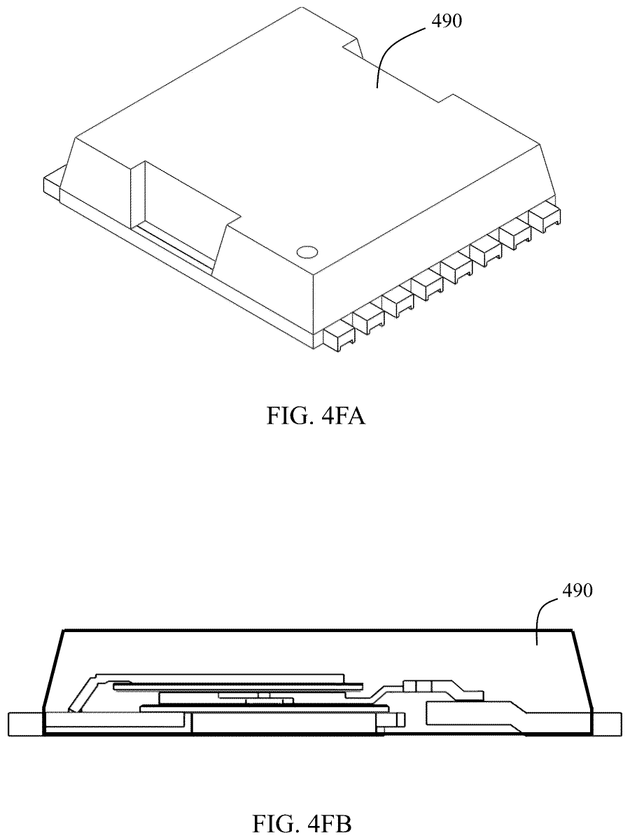

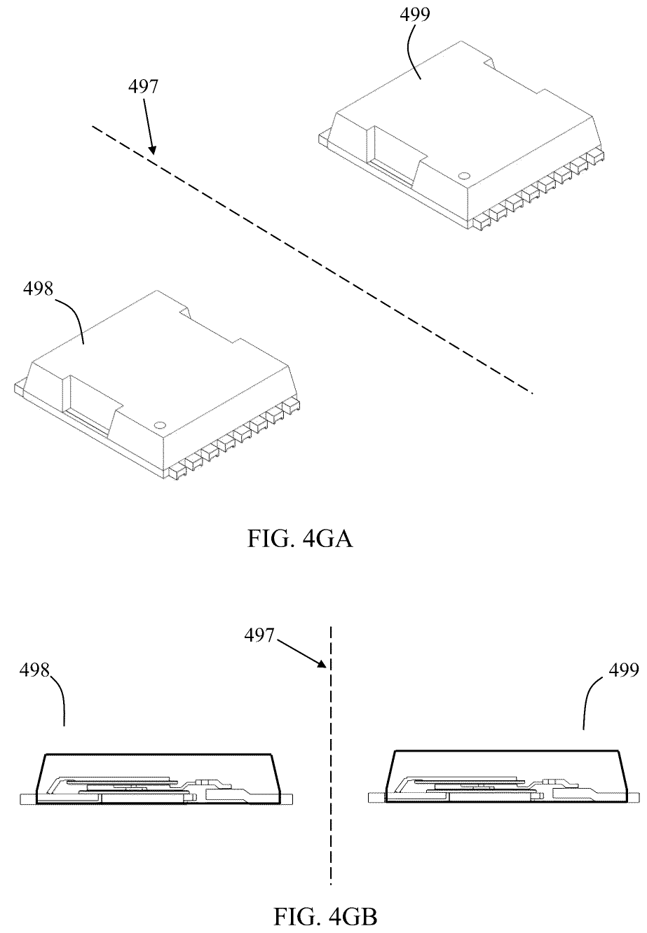

In examples of the present disclosure, the semiconductor package 100 further comprises a plurality of solder layers 449 of FIG. 4BA. The molding encapsulation 190 enclosed the plurality of solder layers 449 of FIG. 4BA.

The lead frame 120 comprises a die paddle 122, a source paddle 124, and a gate paddle 126.

The first high-voltage FET 140 is attached to the die paddle 122. The first high-voltage FET 140 comprises a source electrode 442 of FIG. 4BA and a gate electrode 444 of FIG. 4BA on a front surface of the first high-voltage FET 140; and a drain electrode 146 on a back surface of the first high-voltage FET 140.

The source clip 150 connects the source electrode 442 of FIG. 4BA of the first high-voltage FET 140 to the source paddle 124. In examples of the present disclosure, the source clip 150 comprises an etched section 152 so as to maintain high voltage insulation distance. A thickness of the etched section 152 of the source clip 150 is 50% of a thickness of a portion of the source clip 150 attached to the source electrode 142 of the first high-voltage FET 140. A width of the etched section 152 of the source clip 150 is larger than 200 microns.

The source clip 150 still further comprises a slanted section 154 and an elevated section 156. A position of a top surface of the elevated section 156 of the source clip 150 is higher than a position of a top surface of the second high-voltage FET 170 to facilitate high voltage insulation.

A distance between an edge of source contact of the source clip 150 and an edge of the second high-voltage FET 170 is larger than minimum insulation distance required to so as to facilitate high voltage insulation.

The gate clip 160 is attached to the gate paddle 126. As shown in FIG. 1E, the gate clip 160 comprises a first island 462 of FIG. 4CA on a back side of the gate clip 160 and a second island 464 of FIG. 4CA on a front side of the gate clip 160. A bottom surface of the first island 462 of FIG. 4CA of the gate clip 160 is attached to the gate electrode 444 of FIG. 4BA of the first high-voltage FET 140. A top surface of the second island 464 of FIG. 4CA of the gate clip 160 is attached to the gate electrode 174 of the second high-voltage FET 170.

The second high-voltage FET 170 is flipped and attached to the source clip 150. The second high-voltage FET 170 comprises a source electrode 172 and a gate electrode 174 on a front surface of the second high-voltage FET 170; and a drain electrode 176 on a back surface of the second high-voltage FET 170. In some examples of the present disclosure, the second high-voltage FET 170 has a size and a layout of source and gate electrodes substantially the same as the first high-voltage FET 140. In some other examples of the present disclosure, the second high-voltage FET 170 is identical to the first high-voltage FET 140. The first island 462 and the second island 464 on opposite surfaces of the gate clip 160 have substantially the same shape and size. A center of the second island 464 laterally shifts a predetermined distance T away from a center of the first island 462 and the second island 464 is further away from a first distal end of the gate clip connected to the gate paddle. As shown in FIG. 1E, the second island 464 may be disposed at a second distal end on the front side of the gate clip 160 opposite the first distal end of the gate clip 160 connected to the gate paddle. The first island may be disposed at the predetermined distance T from the second distal end on the back side of the gate clip 160. As shown in the side view FIG. 1D, the second high-voltage FET disposed on the source clip 150 and the gate clip 160 also laterally shifts the predetermined distance T away from the first high-voltage FET 140 in the same direction further away from a distal end of the source clip connecting to the source paddle. The predetermined distance is larger than a minimum insulation distance required to facilitate high voltage insulation.

The drain clip 180 connects the drain electrode 176 of the second high-voltage FET 170 to the die paddle 122.

The molding encapsulation 190 encloses the first high-voltage FET 140, the source clip 150, the gate clip 160, the second high-voltage FET 170, at least a majority portion of the drain clip 180, and a majority portion of the lead frame 120. A majority portion refers to larger than 50%. In examples of the present disclosure, a bottom surface of the lead frame 120 is exposed from the molding encapsulation 190.

In one example, a high-voltage refers to a voltage higher than 400 volts. In another example, a high-voltage refers to a voltage higher than 600 volts.

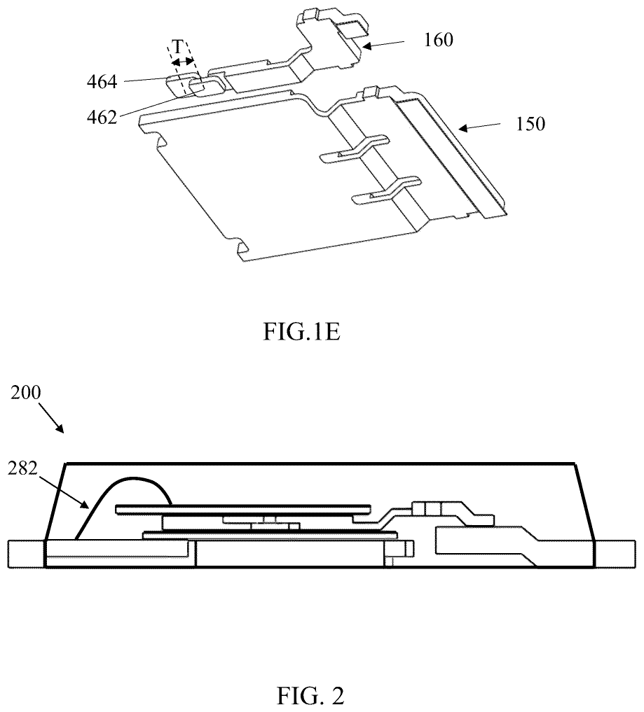

FIG. 2 is a side view of a semiconductor package 200 in examples of the present disclosure. The semiconductor package 200 is similar to the semiconductor package 100 of FIGS. 1A, 1B, 1C, and 1D except that the drain clip 180 of FIG. 1C is replaced by a bond wire 282 of FIG. 2.

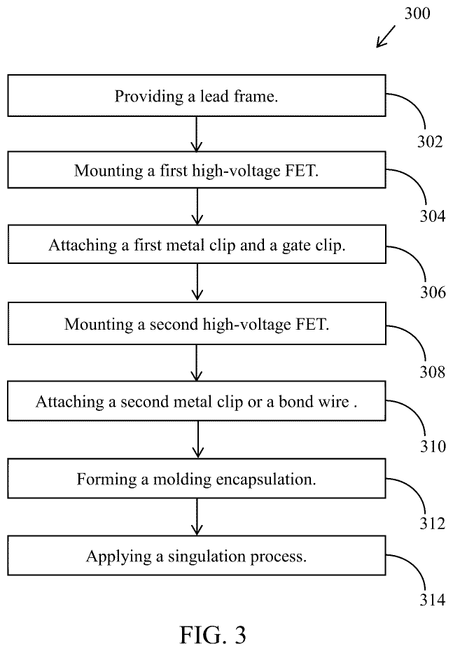

FIG. 3 is a flowchart of a process 300 to develop a semiconductor package in examples of the present disclosure. The process 300 may start from block 302. A plurality of semiconductor packages may be fabricated at the same time. In one example, FIG. 4GA and 4GB show 2 semiconductor packages are fabricated at the same time. The number of semiconductor packages, fabricated at the same time, may vary. For simplicity, FIG. 4AA-4FB show the process steps for fabricating a single semiconductor package.

In block 302, referring now to FIG. 4AA and 4AB, a lead frame 420 is provided. The lead frame 420 comprises a die paddle 422, a source paddle 424, and a gate paddle 426.. Block 302 may be followed by block 304.

In block 304, referring now to FIG. 4BA and 4BB, a first high-voltage FET 440 is mounted. The first high-voltage FET 440 is attached to the die paddle 422. The first high-voltage FET 440 comprises a source electrode 442 and a gate electrode 444 on a front surface of the first high-voltage FET 440; and a drain electrode 446 on a back surface of the first high-voltage FET 440. The drain electrode 446 is electrically connected to the die paddle 422. The source electrode 442 and the gate electrode 444 are surrounded by a passivation layer on the front surface the first high-voltage FET 440. A plurality of solder layers 449 are disposed onto the source electrode 442 and the gate electrode 444 of the first high-voltage FET 440. Block 304 may be followed by block 306.

In block 306, referring now to FIG. 4CA and 4CB, a source clip 450 and a gate clip 460 are mounted. The source clip 450 connects the source electrode 442 of the first high-voltage FET 440 to the source paddle 424. In examples of the present disclosure, the source clip 450 comprises an etched section 452 so as to maintain high voltage insulation distance. A thickness of the etched section 452 of the source clip 450 is 50% of a thickness of a portion of the source clip 450 attached to the source electrode 442 of the first high-voltage FET 440.

The source clip 450 still further comprises a slanted section 454 and an elevated section 456. A position of a top surface of the elevated section 456 of the source clip 450 is higher than a position of a top surface of the second high-voltage FET 470 of FIG. 4DB to facilitate high voltage insulation.

The gate clip 460 is attached to the gate paddle 426. The gate clip 460 comprises a first island 462 on the back side of the gate clip and a second island 464 on the front side of the gate clip. A bottom surface of the first island 462 of the gate clip 160 is attached to the gate electrode 444 of the first high-voltage FET 440. A top surface of the second island 464 of the gate clip 460 is attached to the gate electrode 474 of FIG. 4DB of the second high-voltage FET 470 of FIG. 4DB. Block 306 may be followed by block 308.

In block 308, referring now to FIG. 4DA and 4DB, a second high-voltage FET 470 is flipped and being mounted. The second high-voltage FET 470 is attached to the source clip 450 and the gate clip 460. The second high-voltage FET 470 comprises a source electrode 472 and a gate electrode 474 on a front surface of the second high-voltage FET 470; and a drain electrode 476 on a back surface of the second high-voltage FET 470. The source electrode 472 of the second high-voltage FET 470 is electrically connected to the source clip 450 and the gate electrode 474 of the second high-voltage FET 470 is electrically connected to a top surface of the second island of the gate clip 460. An area of the second high-voltage FET 470 extends beyond edges of the source clip 450. A distance between an edge of the source clip 450 and a corresponding edge of the second high-voltage FET 470 of FIG. 4DB is larger than minimum insulation distance (in one example, 150 microns) required to so as to facilitate high voltage (in one example, 400 volts) insulation.

In examples of the present disclosure, the second high-voltage FET 470 is identical to the first high-voltage FET 440. The first island 462 and the second island 464 on opposite surfaces of the gate clip 460 have substantially the same shape and size. A center of the second island 464 laterally shifts a predetermined distance away from a center of the first island 462 and the second island 464 is further away from an end of the gate clip connected to the gate paddle. As shown in the sideview FIG. 4DB, the second high-voltage FET also laterally shifts the same predetermined distance away from the first high-voltage FET 140 in the same direction. The predetermined distance is larger than a minimum insulation distance required to facilitate high voltage insulation. Block 308 may be followed by block 310.

In block 310, referring now to FIG. 4EA and 4EB, a drain clip 480 or a bond wire 282 of FIG. 2 connects the drain electrode 476 of the second high-voltage FET 470 to the die paddle 422. Block 310 may be followed by block 312.

In block 312, referring now to FIG. 4FA and 4FB, a molding encapsulation 490 is formed. The molding encapsulation 490 encloses the first high-voltage FET 440, the source clip 450, the gate clip 460, the second high-voltage FET 470, at least a majority portion of the drain clip 480, a plurality of solder layers 449, and a majority portion of the lead frame 420. A majority portion refers to larger than 50%. In examples of the present disclosure, a bottom surface of the lead frame 420 is exposed from the molding encapsulation 490. Block 312 may be followed by block 314.

In block 314, referring now to FIG. 4GA and 4GB, a singulation process 497 is applied so as to separate the semiconductor package 498 from adjacent semiconductor packages 499. In examples of the present disclosure, the semiconductor package 498 and the adjacent semiconductor packages 499 are transistor outline leadless (TOLL) surface mounting devices (SMDs).

In examples of the present disclosure, the semiconductor package 498 is of a first rectangular prism shape. The first high-voltage FET 440 is of a second rectangular prism shape. The second high-voltage FET 470 is of a third rectangular prism shape.

In one example, a high-voltage refers to a voltage higher than 400 volts. In another example, a high-voltage refers to a voltage higher than 600 volts.

Those of ordinary skill in the art may recognize that modifications of the embodiments disclosed herein are possible. For example, a number of bond wires may vary. Other modifications may occur to those of ordinary skill in this art, and all such modifications are deemed to fall within the purview of the present invention, as defined by the claims.

1. A semiconductor package comprising:
a lead frame comprising:
a die paddle,
a source paddle, and
a gate paddle;
a first high-voltage field-effect transistor (FET) attached to the die paddle, the first high-voltage FET comprising:
a source electrode and a gate electrode on a front surface of the first high-voltage FET; and
a drain electrode on a back surface of the first high-voltage FET;
a source clip connecting the source electrode of the first high-voltage FET to the source paddle;
a gate clip attached to the gate paddle, the gate clip comprising:
a first island; and
a second island;
a second high-voltage FET being flipped and attached to the source clip, the second high-voltage FET comprising:
a source electrode and a gate electrode on a front surface of the second high-voltage FET; and
a drain electrode on a back surface of the second high-voltage FET;
a drain connection member connecting the drain electrode of the second high-voltage FET to the die paddle; and
a molding encapsulation enclosing the first high-voltage FET, the source clip, the gate clip, the second high-voltage FET, at least a majority portion of the drain connection member, and a majority portion of the lead frame;
wherein a bottom surface of the first island of the gate clip is attached to the gate electrode of the first high-voltage FET; and
wherein a top surface of the second island of the gate clip is attached to the gate electrode of the second high-voltage FET.

2. The semiconductor package of claim 1, wherein the first high-voltage FET and the second high-voltage FET comprises a same size and a same layout of source and gate electrodes.

3. The semiconductor package of claim 2, wherein the second high-voltage FET is identical to the first high-voltage FET.

4. The semiconductor package of claim 2, wherein the first island and the second island on opposite surfaces of the gate clip are of a same shape and of a same size.

5. The semiconductor package of claim 4, wherein a center of the second island laterally shifts a predetermined distance away from a center of the first island.

6. The semiconductor package of claim 4, wherein the second island is disposed at a distal end of the gate clip and is on a front side of the gate clip; and
wherein the first island is disposed at a predetermined distance away from the distal end of the gate clip and is on a back side of the gate clip opposite the front side of the gate clip.

7. The semiconductor package of claim 6, wherein the second high-voltage FET is disposed on the source clip and
the gate clip, wherein the second high-voltage FET laterally shifts the predetermined distance from the first high-voltage FET.

8. The semiconductor package of claim 7, wherein the predetermined distance is larger than a minimum insulation distance required to facilitate a high voltage insulation of four hundred volts.

9. The semiconductor package of claim 1, wherein a high-voltage is higher than four hundred volts.

10. The semiconductor package of claim 1, wherein a high-voltage is higher than six hundred volts.

11. A method for fabricating a semiconductor package, the method comprising the steps of:
providing a lead frame comprising
a die paddle,
a source paddle, and
a gate paddle;
mounting a first high-voltage field-effect transistor (FET) on the die paddle, the first high-voltage FET comprising:
a source electrode and a gate electrode on a front surface of the first high-voltage FET; and
a drain electrode on a back surface of the first high-voltage FET;
attaching a source clip connecting the source electrode of the first high-voltage FET to the source paddle;
attaching a gate clip to the gate paddle, the gate clip comprising:
a first island; and
a second island;
mounting a second high-voltage FET on the source clip, the second high-voltage FET being flipped, the second high-voltage FET comprising:
a source electrode and a gate electrode on a front surface of the second high-voltage FET; and
a drain electrode on a back surface of the second high-voltage FET;
applying a drain connection member connecting the drain electrode of the second high-voltage FET to the die paddle;
forming a molding encapsulation enclosing the first high-voltage FET, the source clip, the gate clip, the second high-voltage FET, at least a majority portion of the drain connection member, and a majority portion of the lead frame; and
applying a singulation process separating the semiconductor package from adjacent semiconductor packages;
wherein a bottom surface of the first island of the gate clip is attached to the gate electrode of the first high-voltage FET; and
wherein a top surface of the second island of the gate clip is attached to the gate electrode of the second high-voltage FET.

12. The method of claim 11, wherein the drain connection member is a drain clip.

13. The method of claim 11, wherein the drain connection member is a bond wire.

14. The method of claim 11, wherein the first high-voltage FET and the second high-voltage FET comprises a same size and a same layout of source and gate electrodes.

15. The method of claim 14, wherein second high-voltage FET is identical to the first high-voltage FET.

16. The method of claim 11, wherein the first island and the second island on opposite surfaces of the gate clip are of a same shape and of a same size.

17. The method of claim 11, wherein a center of the second island laterally shifts a predetermined distance away from a center of the first island.

18. The method of claim 17, wherein the second island is disposed at a distal end of the gate clip and is on a front side of the gate clip; and
wherein the first island is disposed at the predetermined distance away from the distal end of the gate clip and is on a back side of the gate clip opposite the front side of the gate clip.

19. The method of claim 18, wherein the second high-voltage FET is disposed on the source clip; and
wherein the gate clip laterally shifts the predetermined distance from the first high-voltage FET.

20. The method of claim 19, wherein the predetermined distance is larger than a minimum insulation distance required to facilitate high voltage insulation of four hundred volts.
